(19) United States
(12) Patent Application Publication
(10) Pub. No.: US 2012/0129318 A1
(43) Pub. Date: May 24, 2012

(54) ATMOSPHERIC PRESSURE PLASMA ETCHING APPARATUS AND METHOD FOR MANUFACTURING SOI SUBSTRATE

(75) Inventors: Hideto OHNUMA, Atsugi (JP); Hideomi SUZAWA, Atsugi (JP)

(73) Assignee: SEMICONDUCTOR ENERGY LABORATORY CO., LTD., Atsugi-shi (JP)

(21) Appl. No.: 13/298,522

(22) Filed: Nov. 17, 2011

(30) Foreign Application Priority Data
Nov. 24, 2010 (JP) 2010-260994

(51) Int. Cl. H01L 21/762; C23F 1/08

(52) U.S. Cl. 438/458; 156/345.24; 257/E21.568

(57) ABSTRACT

The atmospheric pressure plasma etching apparatus is provided with a state detecting unit for detecting a state of the object to be processed, and the operation of the atmospheric pressure plasma etching apparatus is controlled in accordance with information detected by the state detecting unit. Thus, in the atmospheric pressure plasma etching apparatus, the object to be processed can be etched while the state of the object to be processed is detected. Accordingly, the object to be processed can be etched favorably. Further, an SOI substrate is manufactured using the atmospheric pressure plasma etching apparatus, whereby both reduction in manufacturing cost of the SOI substrate and suppression of peeling in the SOI substrate can be achieved.

### BACKGROUND OF THE INVENTION

1. Field of the Invention

The present invention relates to an atmospheric pressure plasma etching apparatus. In particular, the present invention relates to an atmospheric pressure plasma etching apparatus for etching a stacked layer including a semiconductor thin film. In addition, the present invention relates to a method for manufacturing a semiconductor device using the atmospheric pressure plasma etching apparatus, for example, a method for manufacturing a silicon-on-insulator (SOI) substrate where a single crystal silicon layer is provided on an insulating surface.

2. Description of the Related Art

In recent years, integrated circuits using an SOI substrate where a thin single crystal semiconductor layer is formed on an insulating surface, instead of a bulk silicon wafer, have been developed. The use of an SOI substrate can reduce parasitic capacitance between a drain of a transistor and a substrate; thus, SOI substrates are attracting attention for their ability to improve performance of semiconductor integrated circuits.

One of known methods for manufacturing an SOI substrate is a Smart Cut (registered trademark) method. A summary of a method for manufacturing an SOI substrate by a Smart Cut method is described below. First, hydrogen ions are implanted into a silicon wafer by an ion implantation method, so that a microbubble layer is formed at a predetermined depth from a surface of the silicon wafer. Next, the silicon wafer into which hydrogen ions have been implanted is bonded to another silicon wafer with a silicon oxide film interposed therebetween. Then, by heat treatment, the microbubble layer serves as a cleavage plane and a part of the silicon wafer into which hydrogen ions have been implanted is separated in a thin film shape along the microbubble layer. Accordingly, a single crystal silicon film can be formed over the other bonded silicon wafer. Smart Cut (registered trademark) method may be referred to as a hydrogen ion implantation separation method.

A method has also been proposed in which a single crystal silicon layer is formed over a base substrate made of glass by such a Smart Cut (registered trademark) method (for example, see Reference 1). Since glass substrates can have a larger area and are less expensive than silicon wafers, glass substrates are mainly used for manufacturing liquid crystal display devices and the like. By using such a glass substrate as a base substrate, an inexpensive large-area SOI substrate can be manufactured. However, an SOI substrate manufactured by the above method is likely to have a problem in that separation (peeling) of a single crystal silicon layer from a glass substrate occurs. One of the causes of the problem is that an end portion of the single crystal silicon layer is separated from the glass substrate in a step of forming the single crystal silicon layer over the glass substrate or a step of manufacturing a semiconductor device using the single crystal silicon layer.

In contrast, a method has been proposed in which after a single crystal silicon layer is formed over a glass substrate, an end portion of the single crystal silicon layer is removed (For example, see Reference 2). Specifically, Reference 2 discloses a structure in which the end portion of the single crystal silicon layer formed over the glass substrate is removed using a photolithography process. However, a photoresist necessary for the photolithography process is expensive. Accordingly, a problem occurs in that manufacturing cost of the SOI substrate or a semiconductor device manufactured using the SOI substrate is increased in the case where the end portion of the single crystal silicon layer is removed by the method disclosed in Reference 2.

Therefore, the end portion of the single crystal silicon layer is preferably removed without using a photolithography process in terms of the manufacturing cost. For example, the end portion of the single crystal silicon layer is preferably removed using an atmospheric pressure (normal pressure) plasma etching apparatus disclosed in Reference 3.

[Reference]
[Reference 1] Japanese Published Patent Application No. 2005-252244
[Reference 2] Japanese Published Patent Application No. 2010-177662
[Reference 3] Japanese Published Patent Application No. 2004-235607

### SUMMARY OF THE INVENTION

In the case where the end portion of the single crystal silicon layer is removed using the atmospheric pressure plasma etching apparatus disclosed in Reference 3, it is difficult to remove the end portion with high accuracy as compared to the case where the end portion of the single crystal silicon layer is removed using a photolithography process. In the case where a plurality of single crystal silicon layers are provided over a large-sized glass substrate, for example, distortion of the glass substrate becomes obvious, and it is difficult to keep a constant working distance between the atmospheric pressure plasma etching apparatus and the single crystal silicon layer. Further, in the case where the end portion of the single crystal silicon layer is removed using the atmospheric pressure plasma etching apparatus disclosed in Reference 3, it is difficult to control etching precisely. That is, in the case where the end portion of the single crystal silicon layer is removed using the atmospheric pressure plasma etching apparatus, the following problem is likely to occur: the end portion of the single crystal silicon layer cannot be removed sufficiently due to underetching, or the glass substrate is etched due to overetching, which causes contamination.

In view of the above problem, an object of one embodiment of the present invention is to provide an atmospheric pressure plasma etching apparatus with which an object to be processed can be etched favorably. Further, another object of one embodiment of the present invention is to achieve both reduction in manufacturing cost of an SOI substrate and suppression of peeling in an SOI substrate.

The above object can be achieved in such a manner that the atmospheric pressure plasma etching apparatus is provided with a state detecting unit for detecting a state of the object to be processed, and operation of the atmospheric pressure plasma etching apparatus is controlled in accordance with information detected by the state detecting unit. Note that an optical monitor or the like can be used as the state detecting unit.

That is, one embodiment of the present invention is an atmospheric pressure plasma etching apparatus including a plasma generation source which generates plasma under an atmospheric pressure or a substantially atmospheric pressure atmosphere; a first exit from which the plasma is released; a second exit from which an etching gas for producing an etchant by mixture with the plasma is released; and a state detecting unit for detecting a state of an object to be processed which is etched using the etchant, wherein the operation is controlled in accordance with information detected by the state detecting unit.

Another embodiment of the present invention is a method for manufacturing an SOI substrate including the steps of: irradiating a single crystal semiconductor substrate with accelerated ions to form a fragile region in the single crystal semiconductor substrate; bonding the single crystal semiconductor substrate and a base substrate to each other with an insulating layer interposed therebetween; separating the single crystal semiconductor substrate at the fragile region to form a single crystal semiconductor layer over the base substrate with the insulating layer interposed therebetween; and removing an end portion of the single crystal semiconductor layer using an etchant produced by mixture of an etching gas and plasma which is generated under an atmospheric pressure or a substantially atmospheric pressure atmosphere while a state of the single crystal semiconductor layer is detected.

In the atmospheric pressure plasma etching apparatus according to one embodiment of the present invention, an object to be processed can be etched while a state of the object to be processed is detected. Therefore, the object to be processed can be etched favorably. Further, an SOI substrate is manufactured using the atmospheric pressure plasma etching apparatus, whereby both reduction in manufacturing cost of the SOI substrate and suppression of peeling in the SOI substrate can be achieved.

### BRIEF DESCRIPTION OF THE DRAWINGS

In the accompanying drawings:

FIG. 1A is a view illustrating a structural example of an atmospheric pressure plasma etching apparatus, and FIG. 1B is a flow chart showing an example of operation of the atmospheric pressure plasma etching apparatus;

FIGS. 2A and 2B are views each illustrating a structural example of an atmospheric pressure plasma etching apparatus; and

FIGS. 3A to 3E are cross-sectional views illustrating an example of a method for manufacturing an SOI substrate.

### DETAILED DESCRIPTION OF THE INVENTION

Hereinafter, embodiments of the present invention will be described in detail with reference to the accompanying drawings. Note that the present invention is not limited to the description below, and it is easily understood by those skilled in the art that a variety of changes and modifications can be made without departing from the spirit and scope of the present invention. Therefore, the present invention should not be limited to the descriptions of the embodiments below.

### Embodiment 1

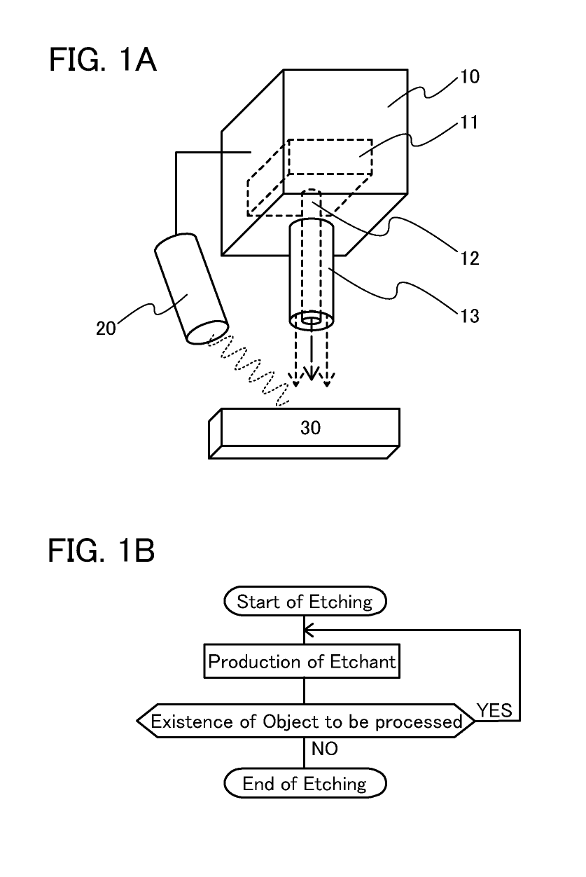

In this embodiment, an atmospheric pressure plasma etching apparatus according to one embodiment of the present invention will be described with reference to FIGS. 1A and 1B.

FIG. 1A illustrates a structural example of an atmospheric pressure plasma etching apparatus in this embodiment. The atmospheric pressure plasma etching apparatus illustrated in FIG. 1A has a main body 10 and an optical monitor 20 attached to the main body 10. Further, the main body 10 has a plasma generation source 11 which generates plasma under an atmospheric pressure or a substantially atmospheric pressure atmosphere, an exit 12 from which the plasma generated in the plasma generation source 11 is released to the outside, and an exit 13 from which an etching gas is released. Note that as the plasma, argon plasma or the like can be used. As the etching gas, a gas can be selected as appropriate depending on an object 30 to be processed which is subjected to etching. Note that the etching gas can be supplied from the outside to the main body 10 or can be stored in a tank provided in the main body 10.

The atmospheric pressure plasma etching apparatus illustrated in FIG. 1A mixes the plasma released from the exit 12 and the etching gas released from the exit 13 outside to produce an etchant. Further, in the atmospheric pressure plasma etching apparatus illustrated in FIG. 1A, the optical monitor 20 detects information on light transmitted through the object 30 to be processed which is subjected to the etching with the use of the etchant or light reflected from the object 30 to be processed. Note that the information is input from the optical monitor 20 to the main body 10. The main body 10 controls operation of the plasma generation source 11 or the like based on the information. Thus, in the atmospheric pressure plasma etching apparatus illustrated in FIG. 1A, the object 30 to be processed can be etched while a state of the object 30 to be processed is detected.

A specific example of operation of the atmospheric pressure plasma etching apparatus illustrated in FIG. 1A will be described with reference to a flow chart shown in FIG. 1B. The flow chart of FIG. 1B shows an example of operation when the object 30 to be processed is subjected to etching. As shown in FIG. 1B, the atmospheric pressure plasma etching apparatus of FIG. 1A can determine whether the object 30 to be processed exists or not using the optical monitor 20 and select whether the etchant continues to be produced (continuation of etching) or the etchant does not continue to be produced (end of etching) depending on the result. Accordingly, in the atmospheric pressure plasma etching apparatus of FIG. 1A, generation of underetching or overetching can be suppressed.

Further, in the atmospheric pressure plasma etching apparatus of FIG. 1A, the exit 13 from which the etching gas is released is provided so as to surround the exit 12 from which the plasma is released. Thus, a region where the etchant is produced is not expanded, and only a desired region can be etched.

Note that in the atmospheric pressure plasma etching apparatus of FIG. 1A, the optical monitor 20 is attached to the main body 10; however, in the atmospheric pressure plasma etching apparatus in this embodiment, the optical monitor 20 can be incorporated in the main body 10.

Further, in the flow chart of FIG. 1B showing the example of the operation of the atmospheric pressure plasma etching apparatus, the example of the operation when the object 30 to be processed is etched while the atmospheric pressure plasma etching apparatus determines whether the object 30 to be processed exists or not using the optical monitor 20 is described; however, in the atmospheric pressure plasma etching apparatus in this embodiment, an operation can be performed in which a thickness of the object 30 to be processed is determined using the optical monitor 20 and etching is ended when a desired thickness is obtained.

### Embodiment 2

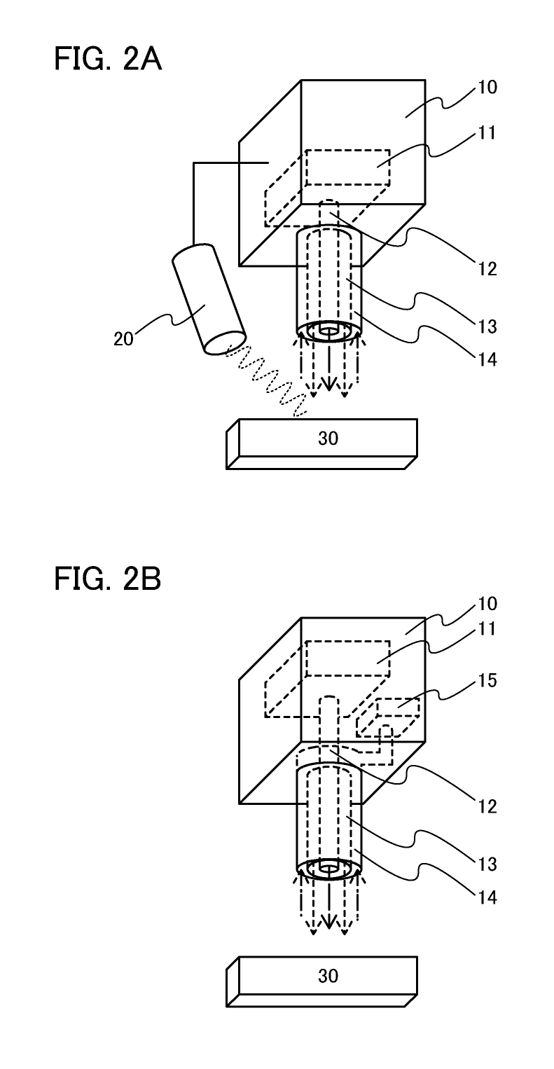

In this embodiment, an atmospheric pressure plasma etching apparatus whose structure is different from that of the atmospheric pressure plasma etching apparatus described in Embodiment 1 will be described with reference to FIG. 2A.

FIG. 2A illustrates a structural example of the atmospheric pressure plasma etching apparatus in this embodiment. The atmospheric pressure plasma etching apparatus of FIG. 2A is different from that of FIG. 1A in that it further includes an inlet 14. A by-product or the like generated due to the etching of the object 30 to be processed can be evacuated (inhaled into the main body 10) to the inlet 14 of the atmospheric pressure plasma etching apparatus of FIG. 2A.

Note that the atmospheric pressure plasma etching apparatus of FIG. 2A has the same components as the atmospheric pressure plasma etching apparatus of FIG. 1A except the inlet 14. Therefore, for a description thereof, the description of Embodiment 1 is to be referred to.

In the atmospheric pressure plasma etching apparatus of FIG. 2A, the inlet 14 is provided so as to surround the exit 13 from which the etching gas is released. Further, in the atmospheric pressure plasma etching apparatus of FIG. 2A, plasma and an etching gas are released from directly above or substantially directly above with respect to the object 30 to be processed through the exit 12 and the exit 13, respectively, and the by-product or the like generated due to the etching is evacuated directly above or substantially directly above through the inlet 14. Thus, diffusion of the by-product or the like generated due to the etching can be suppressed. Note that a unit for evacuating the by-product (an evacuation unit) is not limited to the unit described above with reference to FIG. 2A, and any unit can be used as long as it can achieve the purpose of evacuating the by-product.

### Embodiment 3

In this embodiment, an atmospheric pressure plasma etching apparatus whose structure is different from that of the atmospheric pressure plasma etching apparatus described in Embodiment 1 or 2 will be described with reference to FIG. 2B.

FIG. 2B illustrates a structural example of an atmospheric pressure plasma etching apparatus in this embodiment. In the atmospheric pressure plasma etching apparatus of FIG. 2B, a componential analysis unit 15 is used instead of the optical monitor 20 of the atmospheric pressure plasma etching apparatus of FIG. 2A. In the atmospheric pressure plasma etching apparatus of FIG. 2B, components inhaled into the main body 10 through the inlet 14 can be analyzed by the componential analysis unit 15.

Note that the atmospheric pressure plasma etching apparatus of FIG. 2B has the same components as the atmospheric pressure plasma etching apparatus of FIG. 2A except the componential analysis unit 15. Therefore, for descriptions thereof, the descriptions of Embodiment 1 and 2 are to be referred to.

In the atmospheric pressure plasma etching apparatus of FIG. 2B, components inhaled into the main body 10 by the inlet 14 can be analyzed by the componential analysis unit 15. Thus, an operation similar to that shown in FIG. 1B, such as end of etching when the by-product generated due to the etching of the object 30 to be processed is not included in the components, can be performed.

### Embodiment 4

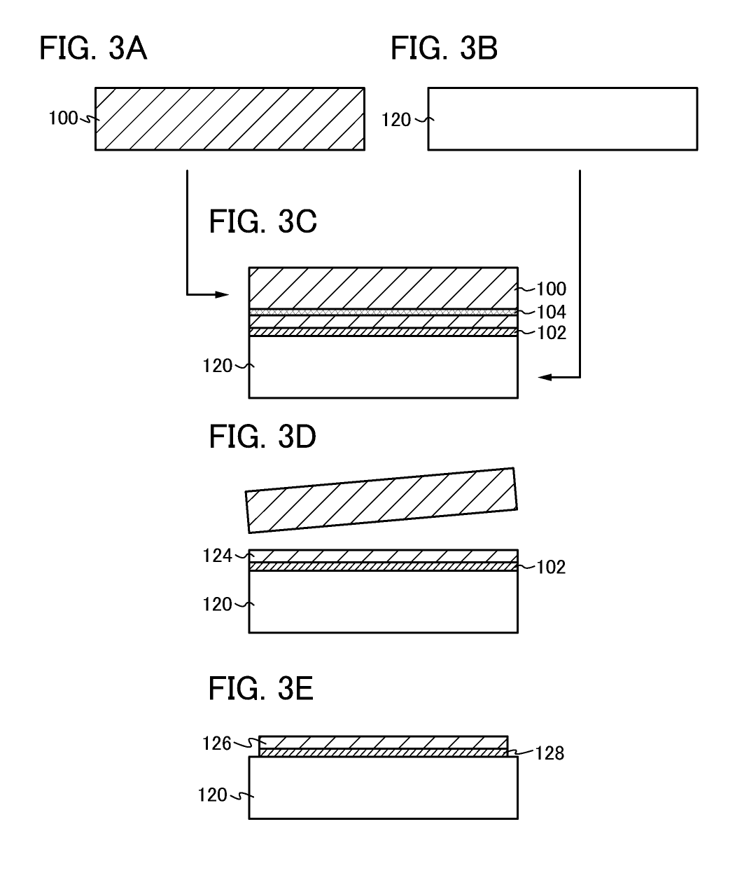

In this embodiment, an example of a method for manufacturing an SOI substrate using the atmospheric pressure plasma etching apparatus described in any one of Embodiments 1 to 3 will be described with reference to FIGS. 3A to 3E.

First, a single crystal semiconductor substrate 100 and a base substrate 120 are prepared (see FIGS. 3A and 3B).

As the single crystal semiconductor substrate 100, for example, a single crystal semiconductor substrate including an element belonging to Group 14, such as a single crystal silicon substrate, a single crystal germanium substrate, or a single crystal silicon germanium substrate, can be used. Alternatively, a compound semiconductor substrate including gallium arsenide, indium phosphide, or the like can be used. Commercial silicon substrate are typically circular in shape with diameters of 5 inches (approximately 125 mm), 6 inches (approximately 150 mm), 8 inches (approximately 200 mm), 12 inches (approximately 300 mm), and 16 inches (approximately 400 mm). Note that the shape of the single crystal semiconductor substrate 100 is not limited to a circular shape, and a single crystal semiconductor substrate processed into, for example, a rectangular shape or the like can also be used.

As the base substrate 120, a substrate formed of an insulator can be used. Specific examples thereof include a variety of glass substrates used in the electronics industry, such as substrates of aluminosilicate glass, aluminoborosilicate glass, and barium borosilicate glass; a quartz substrate; a ceramic substrate; and a sapphire substrate. Further, a single crystal semiconductor substrate such as a single crystal silicon substrate may be used as the base substrate 120. In this embodiment, a case where a glass substrate is used is described. When a plurality of single crystal semiconductor substrates are bonded to a glass substrate serving as the base substrate 120, which can have a large area and is inexpensive, cost can be reduced.

Next, a fragile region 104 with a damaged crystal structure is formed at a predetermined depth from a surface of the single crystal semiconductor substrate 100. After that, the single crystal semiconductor substrate 100 and the base substrate 120 are bonded to each other with an insulating layer 102 interposed therebetween (see FIG. 3C).

The fragile region 104 can be formed by irradiation of the single crystal semiconductor substrate 100 with accelerated ions of hydrogen or the like.

The insulating layer 102 can be formed to have a single layer or stacked layers of an insulating layer such as a silicon oxide film, a silicon oxynitride film, a silicon nitride film, a silicon nitride oxide film, or the like. These films can be formed by a thermal oxidation method, a CVD method, a sputtering method, or the like. Note that when an oxide film such as a silicon oxide film or a silicon oxynitride film is used as the insulating layer 102, bonding strength between the single crystal semiconductor substrate 100 and the base substrate 120 can be increased. When a nitride film such as a silicon nitride film or a silicon nitride oxide film is used as the insulating layer 102, entry of impurities contained in the base substrate 120 into the single crystal semiconductor substrate 100 can be suppressed.

In this specification, silicon oxynitride contains more oxygen than nitrogen, and in the case where measurement is conducted using Rutherford backscattering spectrometry (RBS) and hydrogen forward scattering (HFS), silicon oxynitride preferably contains oxygen, nitrogen, silicon, and hydrogen at concentrations ranging from 50 to 70 atomic %, 0.5 to 15 atomic %, 25 to 35 atomic %, and 0.1 to 10 atomic %, respectively. Further, silicon nitride oxide contains more nitrogen than oxygen, and in the case where measurement is conducted using RBS and HFS, silicon nitride oxide preferably contains oxygen, nitrogen, silicon, and hydrogen at concentrations ranging from 5 to 30 atomic %, 20 to 55 atomic %, 25 to 35 atomic %, and 10 to 30 atomic %, respectively. Note that percentages of nitrogen, oxygen, silicon, and hydrogen fall within the ranges given above, where the total number of atoms contained in the silicon oxynitride or the silicon nitride oxide is defined as 100 atomic %.

Next, heat treatment is performed to separate the single crystal semiconductor substrate 100 at the fragile region 104, whereby a single crystal semiconductor layer 124 is provided over the base substrate 120 with the insulating layer 102 interposed therebetween (see FIG. 3D).

Due to temperature rise in the heat treatment, the element added by the ion irradiation is separated out into microvoids which are formed in the fragile region 104, and the internal pressure of the microvoids is increased. By the pressure increase, the microvoids in the fragile region 104 are changed in volume and a crack is generated in the fragile region 104. Thus, the single crystal semiconductor substrate 100 is separated along the fragile region 104. Since the insulating layer 102 is bonded to the base substrate 120, the single crystal semiconductor layer 124 which is separated from the single crystal semiconductor substrate 100 is provided over the base substrate 120. This heat treatment is performed at a temperature not exceeding the strain point of the base substrate 120.

This heat treatment can be performed using a heating furnace such as a diffusion furnace or a resistance heating furnace, a rapid thermal annealing (RTA) apparatus, a microwave heating apparatus, or the like. For example, in the case of using an RTA apparatus, the heat treatment can be performed at a heating temperature of greater than or equal to 550° C. and less than or equal to 730° C., for a process time of greater than or equal to 0.5 minutes and less than or equal to 60 minutes.

Next, in order to suppress peeling, an end portion of the single crystal semiconductor layer 124 and an end portion of the insulating layer 102 are removed. This removing step is performed using the atmospheric pressure plasma etching apparatus described in any one of Embodiments 1 to 3. That is, the end portion of the single crystal semiconductor layer 124 and the end portion of the insulating layer 102 are removed using an etchant produced by mixture of an etching gas and plasma generated under an atmospheric pressure or a substantially atmospheric pressure atmosphere while the states of the end portions of the single crystal semiconductor layer 124 and the insulating layer 102 are detected. Thus, a single crystal semiconductor layer 126 and an insulating layer 128 which have planar end surfaces (edge portions) are obtained (see FIG. 3E).

Note that in FIG. 3E, the end portions of the single crystal semiconductor layer 124 and the insulating layer 102 are removed; however, the atmospheric pressure plasma etching apparatus described in any one of Embodiments 1 to 3 is used, whereby the degree of freedom of the shape of the end portions is improved. Specifically, the atmospheric pressure plasma etching apparatus described in any one of Embodiments 1 to 3 is used, whereby it is possible to remain the insulating layer 102 and remove only the end portion of the single crystal semiconductor layer 124, for example.

Moreover, in the case where the single crystal semiconductor layer 124 has a mark for product management (this mark is also called an identification number, a wafer identification number, a wafer number, an ID number, or the like), the removal of the end portion of the single crystal semiconductor layer 124 and the removal of a region of the single crystal semiconductor layer where the mark is formed may be performed by the same etching step.

Through the above steps, an SOI substrate where the single crystal semiconductor layer 126 is provided over the base substrate 120 with the insulating layer 128 interposed therebetween can be manufactured.

In the method for manufacturing an SOI substrate described in this embodiment, the step of removing the end portions of the single crystal semiconductor layer 124 and the insulating layer 102 is performed using the atmospheric pressure plasma etching apparatus described in any one of Embodiments 1 to 3. Thus, both reduction in manufacturing cost of the SOI substrate and suppression of peeling in the SOI substrate can be achieved.

This application is based on Japanese Patent Application Serial No. 2010-260994 filed with Japan Patent Office on Nov. 24, 2010, the entire contents of which are hereby incorporated by reference.

What is claimed is:

1. An atmospheric pressure plasma etching apparatus comprising:
a main body, the main body comprising;
a plasma generation source configured to generate plasma under an atmospheric pressure or a substantially atmospheric pressure atmosphere;
a first exit connected to the plasma generation source, the first exit configured to release the plasma;
a second exit surrounding the first exit, the second exit configured to release an etching gas; and
a state detecting unit attached to the main body, the state detecting unit configured to detect a state of an object to be processed.

2. The atmospheric pressure plasma etching apparatus according to claim 1, wherein operation of the atmospheric pressure plasma etching apparatus is controlled in accordance with information detected by the state detecting unit.

3. The atmospheric pressure plasma etching apparatus according to claim 1, wherein the state detecting unit is an optical monitor.

4. The atmospheric pressure plasma etching apparatus according to claim 1, wherein the state detecting unit is a componential analysis unit.

5. An atmospheric pressure plasma etching apparatus comprising:
a main body, the main body comprising:
a plasma generation source configured to generate plasma under an atmospheric pressure or a substantially atmospheric pressure atmosphere;
a first exit connected to the plasma generation source, the first exit configured to release the plasma;
a second exit surrounding the first exit, the second exit configured to release an etching gas;
a state detecting unit attached to the main body, the state detecting unit configured to detect a state of an object to be processed; and
an inlet surrounding the second exit, the inlet configured to evacuate at least a by-product generated due to the object to be processed.

6. The atmospheric pressure plasma etching apparatus according to claim 5, wherein operation of the atmospheric pressure plasma etching apparatus is controlled in accordance with information detected by the state detecting unit.

7. The atmospheric pressure plasma etching apparatus according to claim 5, wherein the state detecting unit is an optical monitor.

8. The atmospheric pressure plasma etching apparatus according to claim 5, wherein the state detecting unit is a componential analysis unit.

9. A method for manufacturing an SOI substrate comprising the steps of:
irradiating a single crystal semiconductor substrate with accelerated ions to form a fragile region in the single crystal semiconductor substrate;
bonding the single crystal semiconductor substrate and a base substrate to each other with an insulating layer interposed therebetween;
separating the single crystal semiconductor substrate at the fragile region to form a single crystal semiconductor layer over the base substrate with the insulating layer interposed therebetween; and
removing an end portion of the single crystal semiconductor layer using an etchant produced by mixture of an etching gas and plasma which is generated under an atmospheric pressure or a substantially atmospheric pressure atmosphere while a state of the single crystal semiconductor layer is detected.

10. The method for manufacturing the SOI substrate according to claim 9, wherein the state is detected by a state detecting unit.

11. The method for manufacturing the SOI substrate according to claim 10, wherein the state detecting unit is an optical monitor or a componential analysis unit.

12. A method for manufacturing an SOI substrate comprising the steps of:
irradiating a single crystal semiconductor substrate with accelerated ions to form a fragile region in the single crystal semiconductor substrate;
bonding the single crystal semiconductor substrate and a base substrate to each other with an insulating layer interposed therebetween;
separating the single crystal semiconductor substrate at the fragile region to form a single crystal semiconductor layer over the base substrate with the insulating layer interposed therebetween; and
removing an end portion of the single crystal semiconductor layer and the insulating layer using an etchant produced by mixture of an etching gas and plasma which is generated under an atmospheric pressure or a substantially atmospheric pressure atmosphere while a state of the single crystal semiconductor layer is detected.

13. The method for manufacturing the SOI substrate according to claim 12, wherein the state is detected by a state detecting unit.

14. The method for manufacturing the SOI substrate according to claim 13, wherein the state detecting unit is an optical monitor or a componential analysis unit.
